(19) United States
(12) Patent Application Publication
(10) Pub. No.: US 2008/0304230 A1
(43) Pub. Date: Dec. 11, 2008

(54) Heat-Sink Structure With Small Fin Gap Area

(76) Inventors: John P. FRANZ, Houston, TX (US); Christian L. Belady, McKinney, TX (US); Wade D. Vinson, Magnolia, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/107,810

(22) Filed: Apr. 23, 2008

Related U.S. Application Data
(60) Provisional application No. 60/943,198, filed on Jun. 11, 2007.

(51) Int. Cl. H05K 7/20

(52) U.S. Cl. 361/687

(57) ABSTRACT

A heat-sink structure includes a base and fins, the latter defining gaps with a cross-sectional area less than 24 mm².

This application claims the benefit of U.S. Provisional Application No. 60/943,198 filed 2007 Jun. 11.

### BACKGROUND OF THE INVENTION

In modular computing systems, module dimensions place constraints on the components that can be employed in a module. Such constraints are often most severe in a module “height” dimension in which modules are stacked. In rack-mount systems, the height dimension is typically vertical, whereas in blade systems, the height dimension is typically horizontal.

Data-handling components such as processors, memory modules, storage disks, and communications devices (including input/output devices and network interfaces) must compete with non-data-handling devices such as power supplies and cooling devices for room within a module. Blade systems alleviate this competition to some extent by moving some non-data handling devices, such as power supplies and fans to the rack in which the blades are mounted. However, some non-data-handling devices, e.g., heat sinks, cannot be moved away from the components, e.g., processors, they are intended to cool and so must compete with data-handling devices for the limited volume and height available per module. What is needed is an approach to increasing the functionality per module.

Herein, related art is described to facilitate understanding of the invention. Related art labeled “prior art” is admitted prior art; related art not labeled “prior art” is not admitted prior art.

### BRIEF DESCRIPTION Of The DRAWINGS

The figures depict implementations/embodiments of the invention and not the invention itself. Note that, while FIGS. 1 and 2 are highly schematic in some respects, the representations of heat sinks in the bottom of FIG. 1 and in FIG. 2 are approximately actual size.

FIG. 1 is a schematic view of a blade system incorporating a heat sink in accordance with an embodiment of the present invention.

FIG. 2 is a combination flow chart and schematic plan view of the interior of the system of FIG. 1.

### DETAILED DESCRIPTION

The present invention provides a heat sink in which the base and fins define a small inter-fin gap area to achieve the cooling performance of more conventional heat sinks, e.g., designed to handle processors with power ratings of 100 watts and above. Such small gap areas are conventionally disfavored because of the resistance they pose to the airflow needed to remove radiated heat. To address this resistance, the present invention provides for the use of fans of sufficient capacity to induce a pressure drop of at least 0.5″ of water through the fins to attain adequate removal of radiated heat. In exchange for the higher cost associated with such fans, the invention permits closely spaced and shorter fins. The shorter fins can be thinner without increasing susceptibility to breakage. Using thin, closely spaced fins results in a higher fin density (e.g., in fins per inch), at least partially compensating for the loss of radiation area due to the shorter fins. The net result is a low-profile heat sink that matches the heat-removal performance of much larger conventional heat sinks.

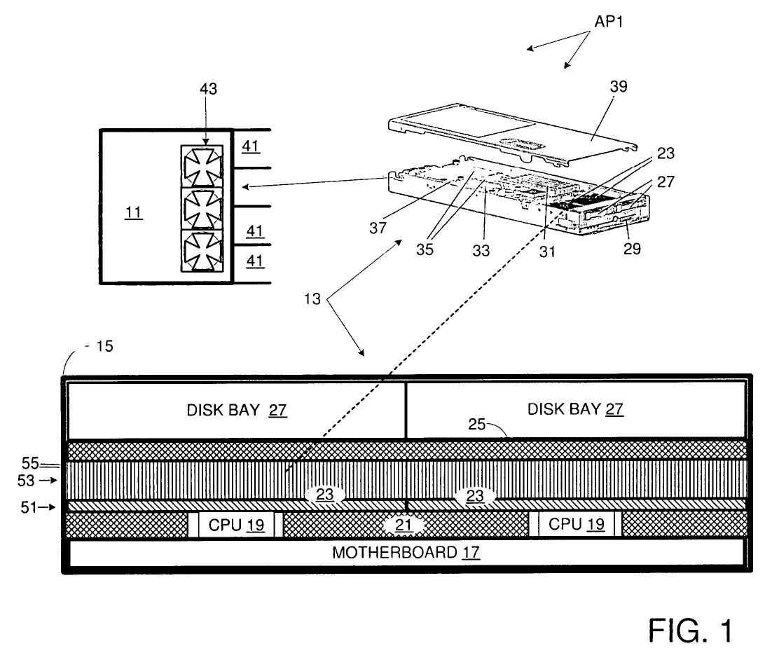

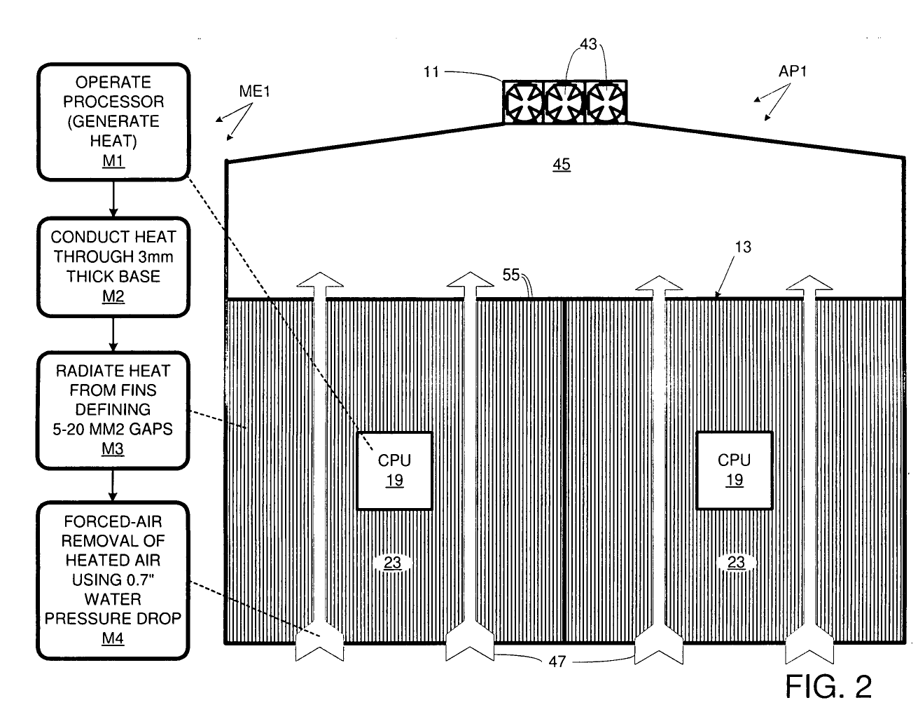

In accordance with an embodiment of the present invention, a computer blade system AP1 comprises a chassis 11 and one or more blades, including blade 13, shown in FIGS. 1 and 2. Blade 13 comprises an enclosure 15, a motherboard 17, processors (CPUs) 19, a processor gasket 21, heat sinks 23, a heat-sink gasket 25, disk drive bays 27, a local I/O connector 29, memory slots 31, a controller 33, mezzanine slots 35 for expansion cards, and an internal USB connector 37. Access to the interior of blade 13 is had by removing an access panel 39 of enclosure 15.

Chassis 11 provides slots 41 for up to four blades; other embodiments provide chasses with other numbers of slots, e.g., sixteen or sixty-four, which may be arranged in one or more dimensions. The chassis 11 provides for electrical connections for communications between blades, power supplies for supplying power to blades, and fans 43 for drawing air through the blades to remove heat (dissipated by processors and other heat-generating components) therefrom. As best seen in FIG. 2, chassis 11 provides a plenum 45 that puts blade 13 and other blades in fluid communication with fans 43. In FIGS. 1 and 2, three fans are indicated, but the invention provides for any number of fans. In general, multiple fans can be used to avoid single points of failure and to allow lower-performance fans to be ganged to achieve high total flow rates. The direction of airflow induced by fans 43 is indicated by arrows 47 in FIG. 2.

Blade 13 can include several heat generating components including any hard drives in hard drive bays 27, memory modules in memory slots 31, controller 33, and add in cards installed in mezzanine slots 35. Generally, however, processors 19 generate the bulk of the heat in blade 13. (The exceptions would involve certain add-in cards that could be added via the mezzanine slots 35.) Processors 19, which can be quad-core Xeon processors, available from Intel Corporation, can consume 100 watts or more of electrical power and dissipate a corresponding amount of heat. The heat must be removed rapidly to avoid a heat buildup that could fatigue or otherwise damage processors 19 and surrounding components.

Each heat sink 23 includes a base 51 and fins 53 of copper. The invention provides for other heat sink materials, e.g., aluminum. However, the relatively low metal volume requirements of the invention permit economical use of relatively costly, but highly thermally conductive copper. A relatively thin base of 2.5 mm (range 1-3 mm) can be used instead of a more conventional 5-10 mm thick base to maintain a relatively low temperature gradient and thus achieve higher efficiency heat removal.

Fins 53 are 13 mm tall (range 8-20 mm, preferably, 11-15 mm compared to a more conventional 30 mm or more for heat sinks designed for 100+ watt processors); adjacent fins define gaps 55 that are as tall as the fins (e.g., 13 mm) and spaced about 0.8 mm (range 0.5-1.2 mm, preferably, 0.7-1.0 mm compared to a conventional gap width of 2.0 mm or greater). The gap areas are less than 24 mm², typically between 5 and 20 mm², inclusive. The fins can be 0.25 mm thick (range 0.1-0.5 mm, preferably, 0.2 to 0.3 mm, compared to a more conventional 0.8-1.2 mm thickness). Combining a 0.25 mm thickness and a 0.8 mm gap, yields a 1.05 mm pitch, which provides for a fin density of 1 per mm (range 18-25 per inch compared to a more conventional 10-14 per inch).

Fans 43 are selected to provide at least 40 cubic-feet-per-minute (cfm) of airflow through blade 13 with a pressure drop of 1″ of water. In general, the fan requirements depend on a number of factors, including 1) the number of fans; 2) the number of blades or other modules they provide airflow for; 3) the pressure drop (0.3″ and typically 0.5″ and above) required by a heat sink; 4) the pressure drop associated with other components in the airflow path associated with the heat sink; and 5) leakage that can divert airflow from the intended path.

To minimize leakage so that fan capacity is not wasted, flow channels are designed so that almost all air moves through heat sinks 23. To this end, heat sinks 23 are dimensioned so that they abut each other and sidewalls of enclosure 15, leaving little or no clearance for airflow. To prevent air from escaping out the top of the fin gaps 55, a structural ceiling is provided. In the illustrated embodiment, disk drive bays 27 and fin gasket 25 serve this purpose. In an alternative embodiment, an enclosure top can serve this purpose. In another embodiment, a ceiling is built into the heat sink—in that case, the fins are attached to both the base and the ceiling. In still another embodiment, the fins are “C” shaped so that they touch each other at their tops, to form channel ceilings.

In some embodiments, gaskets are used to further prevent leakage. In the illustrated embodiment, heat sink gasket 25 is used to ensure a conforming seal between fins 53 and disk drive bays 27, which serve as covers for heat sinks 23. Another such gasket material 21 is used to seal the space below heat sinks 23 and around processors 19 to prevent airflow from flowing under heat sinks 23.

The gasket material can include a closed-cell foam. The closed-cell foam can be Poron, a microcellular polyurethane available from Rogers Corporation. The closed-cell foam can be backed by abrasion resistant material, e.g., a polyester or plastic film such as Mylar (available from DuPont) or Formex (available from Formex Manufacturing, Inc.).

A method ME1 in accordance with an embodiment of the invention is represented by the flow chart of FIG. 2. At method segment M1, a blade and the processors it incorporates are operated so as to generate heat. At method segment M2, the heat is conducted from the processors through a thin (1-3 mm) base and into fins. At method segment M3, heat is radiated from the fins into the low-area gaps between the fins. Herein, the low gap areas are between 2 and 24 mm², typically between 5 and 20 mm². At method segment M4, the heat radiated into the gaps is removed using forced air that establishes a 0.7″ of water pressure drop. More generally, the pressure drop should be at least 0.2″ of water and more specifically above 0.5″ of water.

The use of a high-pressure fan or fans and the elimination of airflow bypass around the heat sinks allows a high-performance low-profile design. Prior art was to use high-power processors only where space was available for large heat sinks or to use lower profile heat sinks with low-power processors (e.g., 30-40 W).

The present invention provides a high-performance low-profile heat sink. The short height results in 97% or greater heat removal efficiency because the entire fin structure is at a relatively uniform temperature. Typical heat sinks use 0.5-1.0 mm thin fins to maintain structural integrity and fin efficiency. However, the shorter fins of the present invention can achieve the same goals with lower thickness. The invention permits a small fin gap, which, along with the thin fins, allows a high fin density. The high fin density allows an adequate total fin radiation area given the short height. Keeping the base structure thin keeps the fin-height-to-base ratio high and using vapor chamber technicality to maximize thermal spreading. Applying proper ducting and gasketing to prevent airflow bypass and keep all airflow molecules over working surfaces. The use of higher-pressure fans provides high airflow despite small air channel (fin gap) dimensions.

The inventions results include more efficient cooling for the given space. This advantage can be leveraged to allow higher power processors for a given heat sink size. Alternatively, a given power processor can be used with a smaller heat sink and thus in the context of a smaller overall system, and thus denser rack and blade systems. This in turn, lowers costs since less rack space is used. Alternatively, the high fan pressure-drop requirement can be reduced, e.g., to relax the power-consumption burden on the data center. These and other variations upon and modifications to the illustrated embodiments are provided for by the present invention, the scope of which is defined by the following claims.

What is claimed is:

1. A heat-sink structure comprising a heat sink having a base and fins, said fins extending orthogonally from said base and defining gaps with an average cross-sectional area less than 24 mm².

2. A heat sink structure as recited in claim 1 wherein said cross-sectional area is between 5 mm² and 20 mm².

3. A heat-sink structure as recited in claim 1 wherein said fins are 10-15 mm tall and arranged on a 1 mm+/−0.3 mm pitch.

4. A heat-sink structure as recited in claim 1 wherein said fins have an average thickness between 0.2 mm and 0.3 mm. (<0.4 mm)

5. A heat-sink structure as recited in claim 1 wherein said gaps are enclosed on four sides by said base, adjacent pairs of said fins, and a cover.

6. A heat-sink structure as recited in claim 5 further comprising one or more fans for establishing a pressure drop along said fins of at least 0.5″ of water.

7. A heat-sink structure as recited in claim 5 further comprising a disk-drive bay serving as at least part of said cover and a gasket contacting said disk drive bay and said fins so as to form an airtight seal between said disk-drive bay and said fins.

8. A heat-sink structure as recited in claim 7 further comprising a chassis 11 and a blade 13, said fins being fixed within said blade and said fans being fixed within said chassis.

9. A heat-sink structure as recited in claim 1 wherein said base is between 1.5 mm and 3.5 mm thick.

10. A method comprising:
operating a processor so that it generates heat;
conducting heat from said processor using a heat sink;
radiating heat from said heat sink using fins defining gaps between adjacent fins and from said base to tops of said fins with average cross-sectional areas less than 24 mm².

11. A method as recited in claim 10 wherein said gap area is between 5 mm² and 20 mm², inclusive.

12. A method as recited in claim 10 further comprising removing heat from said gaps using forced air establishing a pressure drop of at least 0.5″ of water through said gaps.

13. A method as recited in claim 10 wherein said base is between 1.5 and 3.5 mm thick.
